(19) United States
(12) Patent Application Publication
(10) Pub. No.: US 2026/0019088 A1
(43) Pub. Date: Jan. 15, 2026

(54) SUCCESSIVE APPROXIMATION A/D CONVERTER

(71) Applicant: ROHM CO., LTD., Kyoto-shi (JP)

(72) Inventor: Yoshiaki FUJIMOTO, Kyoto-shi (JP)

(21) Appl. No.: 19/336,723

(22) Filed: Sep. 23, 2025

Related U.S. Application Data
(63) Continuation of application No. PCT/JP2024/011591, filed on Mar. 25, 2024.

(30) Foreign Application Priority Data
Mar. 30, 2023 (JP) 2023-056552

(51) Int. Cl. H03M 1/46

(52) U.S. Cl. CPC H03M 1/46

(57) ABSTRACT

A successive approximation A/D converter includes a D/A converter that generates an analog output signal including an analog signal corresponding to a digital input, a comparator that outputs a comparison result between the analog signal and an analog input signal, and a control circuit that generates a digital input on the basis of the comparison result. The control circuit includes a reference register and a plurality of comparison registers each synchronized with the reference register. The reference register outputs a comparison signal obtained by capturing the comparison result. Each of the plurality of comparison registers corresponds to each bit from a most significant bit to a least significant bit, captures the comparison signal of a corresponding bit, and outputs a data signal indicating each bit from the most significant bit to the least significant bit.

### CROSS REFERENCE TO RELATED APPLICATIONS

This application is a continuation under 35 U.S.C. §120 of PCT/JP2024/011591, filed Mar. 25,2024, which is incorporated herein by reference, and which claimed priority to Japanese Application No. 2023-056552, filed Mar. 30, 2023 The present application likewise claims priority under 35 U.S.C. §119 to Japanese Application No. 2023-056552, filed Mar. 30, 2023, the entire content of which is also incorporated herein by reference.

### BACKGROUND

### 1. Technical Field

The present disclosure relates to a successive approximation A/D converter.

### 2. Description of the Related Art

A successive approximation A/D converter (hereinafter, also referred to as a “successive approximation ADC”) that converts an analog input signal into a digital output signal is known. In the successive approximation ADC, an analog input signal is sampled, a comparator performs successive approximation of a sampling result with a signal corresponding to a digital input for each bit of a digital output signal, and the digital output signal is generated according to a result of the successive approximation.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a schematic block diagram of a successive approximation ADC according to a first embodiment;

FIG. 2 is a block diagram for describing a control circuit according to a comparative technology;

FIG. 3 is a diagram illustrating an example of a delay of a comparison signal input to a D flip-flop circuit according to the comparative technology;

FIG. 4 is a diagram for describing a converted value of an analog input signal when Td2=Td1=Td0 and Td2<Td1=Td0;

FIG. 5 is a block diagram for describing a function of a control circuit according to the first embodiment;

FIG. 6 is a diagram illustrating a circuit configuration of the control circuit according to the first embodiment; and

FIG. 7 is a schematic block diagram of a successive approximation ADC according to a second embodiment.

### DETAILED DESCRIPTION

### Outline

An outline of some exemplary embodiments of the present disclosure will be described. This outline describes some concepts of one or a plurality of embodiments in a simplified manner for the purpose of basic understanding of the embodiments as an introduction to detailed description that follows and does not limit an extent of the invention or disclosure. This outline is not a comprehensive outline of all possible embodiments and is not intended to specify important elements of all the embodiments or delineate the scope of some or all aspects. For convenience, “one embodiment” is used in some cases to refer to one embodiment (example or variation) or a plurality of embodiments (examples or variations) disclosed in the present specification.

A successive approximation A/D converter according to one embodiment generates a digital output signal corresponding to an analog input signal. The successive approximation A/D converter includes a D/A converter that generates an analog output signal including an analog signal corresponding to a digital input, a comparator that outputs a comparison result between the analog signal and the analog input signal, and a control circuit that generates the digital input on the basis of the comparison result. The comparator successively outputs the comparison result in order to determine each bit from a most significant bit to a least significant bit of the digital output signal. The control circuit includes a reference register and a plurality of comparison registers each synchronized with the reference register. The reference register outputs a comparison signal obtained by capturing the comparison result. Each of the plurality of comparison registers captures the comparison signal for determining a corresponding bit among the most significant bit to the least significant bit, and outputs a data signal indicating each bit from the most significant bit to the least significant bit.

According to this configuration, the reference register captures the comparison result output from the comparator to acquire the comparison signal, and the comparison signal is input to each of the plurality of comparison registers. As a result, even if the output by the comparator is delayed, this delay is reset by the reference register. As a result, a variation in delay input to each of the plurality of comparison registers is suppressed, and DNL can be improved.

In one embodiment, the control circuit may further include a successive approximation register that generates a digital input on the basis of the comparison result. The successive approximation register may use the comparison signal obtained by the reference register capturing the comparison result for determining an (n−1)-th bit from the most significant bit in order to generate the digital input for determining an n-th (n is an integer of 2 or larger) bit from the most significant bit.

In one embodiment, the successive approximation register may use the comparison signal obtained by the reference register capturing the comparison result for determining the (n−1)-th bit from the most significant bit, and the data signal output from the comparison register corresponding to a higher-order bit than the (n−1)-th bit from the most significant bit in order to generate the digital input for determining the n-th (n is an integer of 3 or larger) bit from the most significant bit.

In one embodiment, the successive approximation register may include a plurality of selectors that respectively acquire a data signal output from a corresponding comparison register among the plurality of comparison registers and the comparison signal and selects one of the acquired signals. The selector corresponding to the (n−1)-th bit from the most significant bit may select the comparison signal obtained by the reference register capturing the comparison result for determining the (n−1)-th bit from the most significant bit in order to generate the digital input for determining the n-th bit from the most significant bit. The selector corresponding to a higher-order bit than the (n−1)-th bit from the most significant bit may select the data signal output from the corresponding comparison register in order to generate the digital input for determining the n-th bit from the most significant bit.

In one embodiment, the reference register may include a D flip-flop circuit.

In one embodiment, each of the reference register and the plurality of comparison registers may include the D flip-flop circuit and configured to operate in response to an identical clock signal.

### Embodiments

A preferred embodiment is hereinafter described with reference to the drawings. The same or equivalent components, members, and processes illustrated in the drawings are assigned with the same reference signs, and description thereof is not repeated appropriately. The embodiments are not intended to limit the disclosure or invention but serve as an example, and all features described in the embodiments and combinations thereof are not necessarily essential to the disclosure or invention.

### First Embodiment

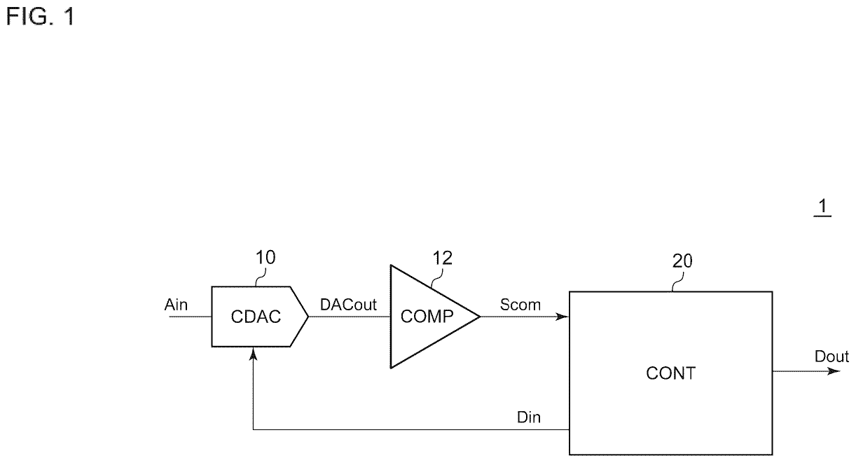

FIG. 1 is a schematic block diagram of a successive approximation ADC 1 according to a first embodiment. The successive approximation ADC 1 generates a digital output signal Dout corresponding to an analog input signal Ain. The successive approximation ADC 1 includes a capacitive DAC 10, a comparator 12, and a control circuit 20.

The digital output signal Dout forms m-bit (m: an integer of 1 or larger) digital data. In the present embodiment, an example in which the output signal Dout is 3-bit digital data will be described. Hereinafter, for the 3-bit digital data, a most significant bit is bit2, a next bit is bit1, and a least significant bit is bit0.

The capacitive DAC 10 according to the present embodiment generates an analog output signal DACout including an analog signal corresponding to a digital input Din. Specifically, the capacitive DAC 10 holds a signal obtained by sampling the analog input signal Ain. The capacitive DAC 10 generates the output signal DACout including a difference between the held signal and the digital input Din.

A configuration of the capacitive DAC 10 is not particularly limited, but the capacitive DAC 10 according to the present embodiment includes a plurality of capacitors provided in a ladder shape. The input signal Ain is sampled by inputting the analog input signal Ain to the plurality of capacitors. By supplying a voltage corresponding to the digital input Din to each of the plurality of capacitors, the output signal DACout including a difference between the signal obtained by sampling and the signal corresponding to the digital input Din is generated.

The comparator 12 generates a comparator signal Scom indicating a comparison result between the sampled analog input signal Ain and the analog signal corresponding to the digital input Din on the basis of the output signal DACout. The comparator 12 may generate a high comparator signal Scom in a case where the sampled analog input signal Ain is larger than the analog signal corresponding to the digital input Din. The comparator 12 may generate a low comparator signal Scom in a case where the sampled analog input signal Ain is not larger than the analog signal corresponding to the digital input Din.

The comparator 12 successively outputs the comparison result in order to determine each bit from the most significant bit to the least significant bit of the digital output signal Dout. Specifically, the comparator 12 successively generates the comparator signal Scom for each of bit0 to bit2. More specifically, the comparator 12 generates the comparator signal Scom in the order of bit2, bit1, and bit0. Specifically, the comparator 12 outputs the comparison result corresponding to the digital input Din for determining bit2, then outputs the comparison result corresponding to the digital input Din for determining bit1, and then outputs the comparison result corresponding to the digital input Din for determining bit0.

The control circuit 20 generates the digital input Din on the basis of the comparator signal Scom. The control circuit 20 generates the digital output signal Dout on the basis of the comparator signal Scom of bit0 to bit2. Specifically, the control circuit 20 generates the digital input Din for determining bit2, then generates the digital input Din for determining bit1, and then generates the digital input Din for determining bit0.

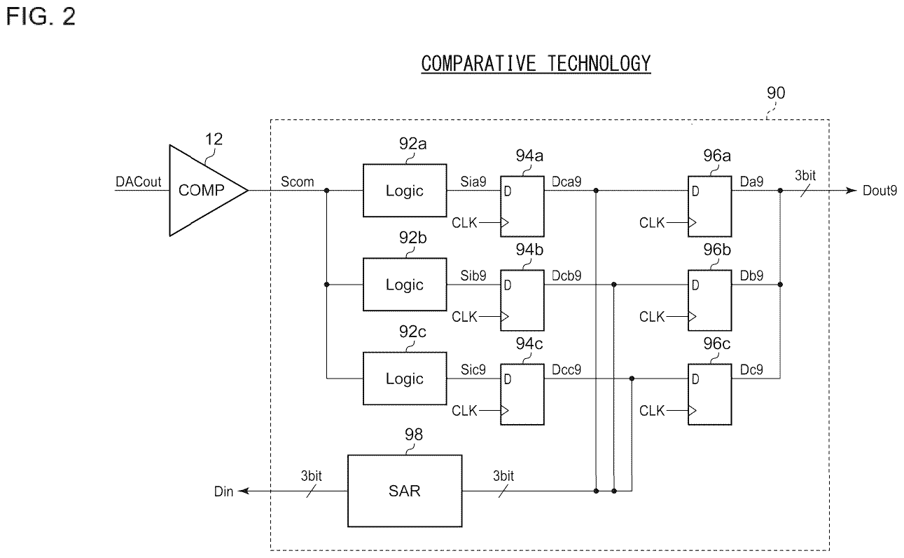

Before describing a function and a configuration of the control circuit 20 according to the present embodiment, a control circuit according to a comparative technology will be described. FIG. 2 is a block diagram for describing a control circuit 90 according to the comparative technology. The control circuit 90 according to the comparative technology includes logic circuits 92a to 92c, D flip-flop circuits 94a to 94c and 96a to 96c, and a successive approximation register 98.

The logic circuits 92a to 92c input the input comparator signal Scom to the D flip-flop circuits 94a to 94c as comparison signals Sia9 to Sic9. Specifically, the logic circuit 92a inputs the comparator signal Scom for determining bit2 to the D flip-flop circuit 94a as the comparison signal Sia9. The logic circuit 92b inputs the comparator signal Scom for determining bit1 to the D flip-flop circuit 94b as the comparison signal Sib9. The logic circuit 92c inputs the comparator signal Scom for determining bit0 to the D flip-flop circuit 94c as the comparison signal Sic9.

The D flip-flop circuits 94a to 94c capture the comparison signals Sia9 to Sic9 in synchronization with a clock signal CLK, and input data signals Dca9 to Dcc9 to the D flip-flop circuits 96a to 96c, respectively. Specifically, the D flip-flop circuit 94a captures the comparison signal Sia9 and inputs the data signal Dca9 indicating bit2 to the D flip-flop circuit 96a. The D flip-flop circuit 94b captures the comparison signal Sib9 and inputs the data signal Dcb9 indicating bit1 to the D flip-flop circuit 96b. The D flip-flop circuit 94c captures the comparison signal Sic9 and inputs the data signal Dcc9 indicating bit0 to the D flip-flop circuit 96c.

The D flip-flop circuits 96a to 96c capture the data signals Dca9 to Dcc9 and output the output data Da9 to Dc9, respectively, in synchronization with the clock signal CLK. On the basis of the output data Da9 to Dc9, the 3-bit digital data is generated as an output signal Dout9.

The successive approximation register 98 generates a 3-bit digital input Din on the basis of the 3-bit data corresponding to the data signals Dca9 to Dcc9. Specifically, when successive approximation is started, the successive approximation register 98 generates the digital input Din for determining bit2 of the sampled input signal Ain. Hereinafter, the successive approximation register 98 generates the digital input Din for determining bit1 and bit of the sampled input signal Ain according to the comparison result of the comparator 12.

The comparison signals Sia9 to Sic9 captured by the D flip-flop circuits 94a to 94c, respectively, are delayed as compared with the comparator signal Scom. This delay includes a delay in the logic circuits 92a to 92c and a delay occurring in each comparison of the comparator 12 by a circuit configuration other than the logic circuits 92a to 92c. Therefore, delays of different lengths occur in each of the comparison signals Sia9 to Sic9.

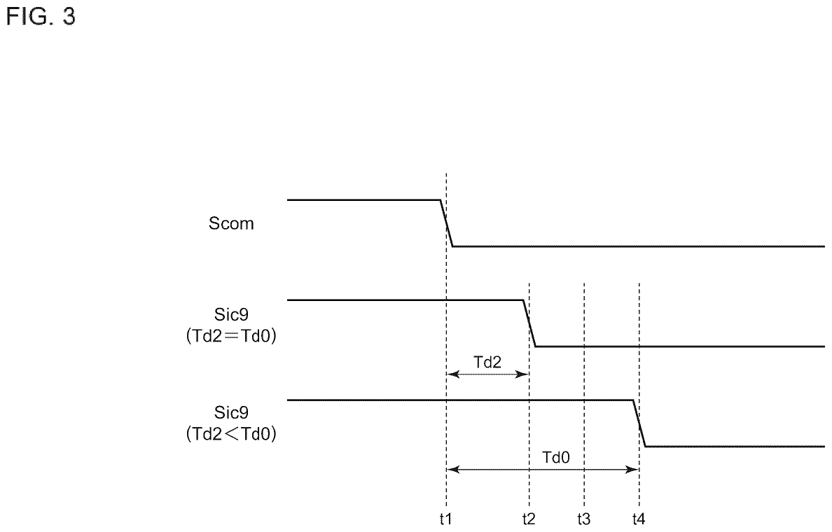

FIG. 3 is a diagram illustrating an example of the delay of the comparison signal Sic9 input to the D flip-flop circuit 94c according to the comparative technology. Herein, the length of the delay of the comparison signal Sia9 is set to Td2, the length of the delay of the comparison signal Sib9 is set to Td1, and the length of the delay of the comparison signal Sic9 is set to Td0.

FIG. 3 illustrates the comparator signal Scom, the comparison signal Sic9 when Td2=Td0, and the comparison signal Sic9 when Td2<Td0 in this order from the top. Herein, it is assumed that Td2 is the same when Td2-Td0 and when Td2<Td0.

An initial value of the comparator signal Scom is high and then becomes low or high according to the comparison result. In the example illustrated in FIG. 3, the comparator signal Scom indicates that the comparison result is low. In the example illustrated in FIG. 3, the comparator signal Scom switches from high to low at timing t1. The comparison signal Sic9 is delayed from the comparator signal Scom. Specifically, in a case of Td2=Td0, the comparison signal Sic9 switches from high to low at timing t2 delayed from timing t1 by Td2 (=Td0). In a case of Td2<Td0, the comparison signal Sic9 switches from high to low at timing further delayed from timing t2, specifically, switches from high to low at timing t4 delayed from timing t1 by Td0.

The D flip-flop circuit 94c captures the comparison signal Sic9 in response to the clock signal CLK (for example, in response to leading of the clock signal CLK). In a case of Td2=Td0, when the D flip-flop circuit 94c captures the comparison signal Sic9 at timing t3 (timing delayed by a time longer than Td2 and shorter than Td0 from timing t1), the D flip-flop circuit 94c can capture low data. In contrast, in a case of Td2<Td0, when the D flip-flop circuit 94c captures the comparison signal Sic9 at timing t3, the D flip-flop circuit 94c captures high data.

In this manner, the data captured by the D flip-flop circuit 94c might be different between a case of Td2=Td0 and a case of Td2<Td0. Since the length of the delay also depends on magnitude of the analog input signal Ain, the analog input signal Ain needs to be lower than that when Td2=Td0 in order for the D flip-flop circuit 94c to capture the low data. As a result, a reference of low and high in the D flip-flop circuit 94c is offset to a negative side.

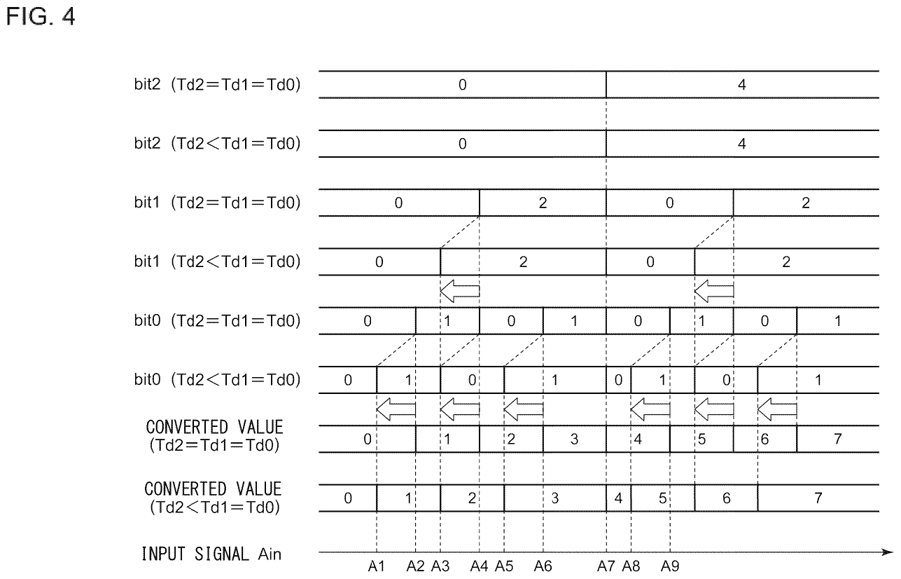

FIG. 4 is a diagram for describing a converted value of the input signal Ain when Td2=Td1=Td0 and Td2<Td1=Td0. FIG. 4 illustrates the data of bit2, the data of bit1, the data of bit0, and the converted value of the input signal Ain for each of Td2=Td1=Td0 and Td2<Td1=Td0 in this order from the top. The abscissa represents the input voltage Ain.

In the example illustrated in FIG. 4, when Td2=Td1=Td0, the reference of high or low of bit2 is the input voltage Ain of A7. That is, bit2 becomes high (4) when the input signal Ain is A7 or larger and becomes low (0) when the input signal Ain is smaller than A7. When Td2<Td1=Td0, similarly, the reference of high or low of bit2 is the input voltage Ain of A7.

Focusing on the input signal Ain smaller than A7, when Td2=Td1=Td0, the reference of high or low of bit1 is the input voltage Ain of A4. That is, bit1 becomes high (2) when the input signal Ain is A4 or larger and becomes low (0) when the input signal Ain is smaller than A4. In a case of Td2<Td1, as described above, the reference of bit1 is offset to a negative side as compared with a case of Td2=Td1. Specifically, when Td2<Td1=Td0, the reference of high or low of bit1 lowers from the input voltage Ain of A4 to A3. Also, for the reference of bit1 in the input signal Ain of A7 or larger, in a case of Td2<Td1=Td0, the reference of high or low is offset to a negative side as compared with a case of Td2=Td1=Td0.

Focusing on the input signal Ain smaller than A4, when Td2=Td1=Td0, the reference of high or low of bit0 is the input voltage Ain of A2. Therefore, bit0 becomes high (1) when the input signal Ain is A2 or larger and becomes low (0) when the input signal Ain is smaller than A2. In a case of Td2<Td0, as described above, the reference of bit0 is offset to a negative side as compared with a case of Td2=Td0. Specifically, when Td2<Td1=Td0, the reference of high or low of bit0 lowers from the input voltage Ain of A2 to Al. Also for the reference of bit0 in the input signal Ain of A4 or larger, in a case of Td2<Td1=Td0, the reference of high or low is offset to a negative side as compared with a case of Td2=Td1=Td0.

As described above, since the references in bit1 and bit0 are offset to a negative side, DNL deteriorates when Td2<Td1=Td0 in a case of using the control circuit 90 according to the comparative technology. In a case of Td2=Td1=Td0, an interval of the input signal Ain is substantially equal for each converted value. In contrast, in a case of Td2<Td1=Td0, the interval of the input signal Ain in each converted value varies. For example, in a case of Td2<Td1=Td0, a range of the converted value 3 is enlarged from A6 to A7 to A5 to A7, and a range of the converted value 4 is reduced from A7 to A9 to A7 to A8, as compared with a case of Td2=Td1=Td0. As a result, the input signal Ain is easily converted into the converted value 3, and the input signal Ain is hardly converted into 4. As described above, in a case where the control circuit 90 according to the comparative technology is used, the interval of the input signal Ain in each converted value varies, and DNL deteriorates.

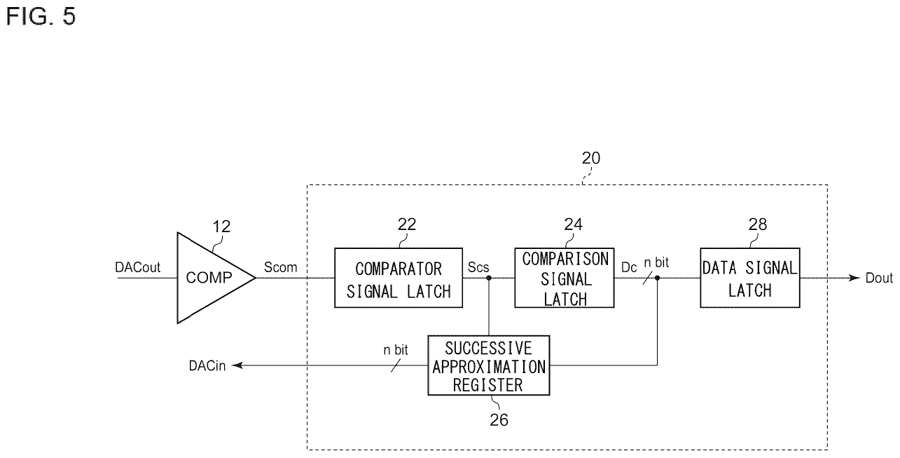

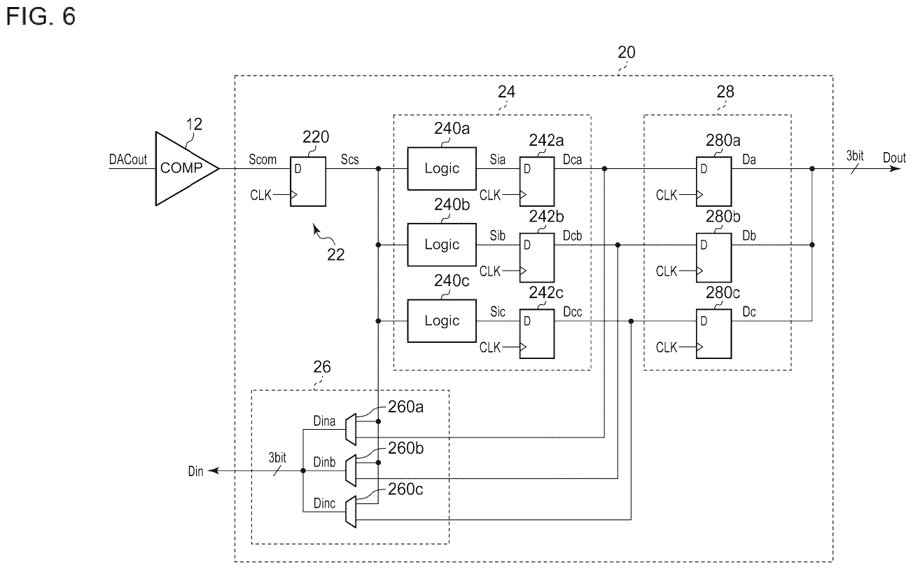

The function and configuration of the control circuit 20 according to the first embodiment will be described with reference to FIG. 5 and FIG. 6. FIG. 5 is a block diagram for describing the function of the control circuit 20 according to the first embodiment. FIG. 6 is a diagram illustrating a circuit configuration of the control circuit 20 according to the first embodiment.

As illustrated in FIG. 5, the control circuit 20 according to the present embodiment includes a comparator signal latch 22, a comparison signal latch 24, a successive approximation register 26, and a data signal latch 28.

The comparator signal latch 22 latches (specifically, holds) the comparator signal Scom from the comparator 12 and inputs a comparison signal Scs obtained by the latch to the successive approximation register 26 and the comparison signal latch 24.

The comparison signal latch 24 latches (specifically, holds) the input comparison signal Scs, and inputs an m-bit (3-bit in the present embodiment) data signal Dc obtained by the latch to the successive approximation register 26 and the data signal latch 28.

The successive approximation register 26 generates the digital input Din on the basis of the comparison result of the comparator 12. Specifically, the successive approximation register 26 generates an m-bit (3-bit in the present embodiment) digital input Din according to the input comparison signal Scs and signal Scr.

The data signal latch 28 latches (specifically, holds) the input data signal Dc and generates the digital output signal Dout.

As illustrated in FIG. 6, the comparator signal latch 22 includes a D flip-flop circuit 220. The D flip-flop circuit 220 functions as a reference register. The D flip-flop circuit 220 outputs the comparison signal Scs obtained by capturing the comparison result of the comparator 12. Specifically, the D flip-flop circuit 220 holds the comparator signal Scom in synchronization with the clock signal CLK and inputs the held signal as the comparison signal Scs to the comparison signal latch 24 and the successive approximation register 26.

The comparison signal latch 24 includes logic circuits 240a to 240c and D flip-flop circuits 242a to 242c. The logic circuits 240a to 240c input comparison signals Sia to Sic corresponding to the input comparison signal Scs to the D flip-flop circuits 242a to 242c. Specifically, the logic circuit 240a inputs the comparison signal Scs for determining bit2 to the D flip-flop circuit 242a as the comparison signal Sia. The logic circuit 240b inputs the comparison signal Scs for determining bit1 to the D flip-flop circuit 242b as the comparison signal Sib. The logic circuit 240c inputs the comparison signal Scs for determining bit0 to the D flip-flop circuit 242c as the comparison signal Sic.

Each of the D flip-flop circuits 242a to 242c functions as a comparison register. The D flip-flop circuits 242a to 242c capture the comparison signals Sia to Sic for determining corresponding bits among the most significant bit to the least significant bit of the output signal Dout, and output data signals Dca to Dcc indicating bits from the most significant bit to the least significant bit, respectively.

Each of the D flip-flop circuits 242a to 242c operates in synchronization with the D flip-flop circuit 220. The D flip-flop circuits 242a to 242c output the data signals Dca to Dcc corresponding to the comparison signals Sia to Sic, respectively, to the successive approximation register 26 and the data signal latch 28 in synchronization with the clock signal CLK.

For example, the D flip-flop circuit 242a holds the comparison signal Sia and outputs the signal Sia corresponding to bit2 in synchronization with the clock signal CLK. The D flip-flop circuit 242b holds the comparison signal Sib and outputs the signal Sib corresponding to bit1 in synchronization with the clock signal CLK. The D flip-flop circuit 242c holds the comparison signal Sic and outputs the signal Sic corresponding to bit0 in synchronization with the clock signal CLK.

The successive approximation register 26 uses the comparison signal Scs obtained by the D flip-flop circuit 220 capturing the comparison result Scom for determining the (n−1)-th bit from the most significant bit in order to generate the digital input Din for determining the n-th (herein, n is an integer of 2 or larger) bit from the most significant bit of the output signal Dout.

Herein, an example in which n=3 will be described. In this case, the successive approximation register 26 generates the digital input Din for determining bit0 (third bit from the most significant bit). At that time, the successive approximation register 26 uses the comparison signal Scs obtained by the D flip-flop circuit 220 capturing the comparison result Scom for determining bit1 (second bit from the most significant bit). Herein, a data signal Dcb indicating bit1 is output through processing of the logic circuit 240b and the D flip-flop circuit 242b. Therefore, the data signal Dcb is delayed as compared with the comparison signal Scs. Therefore, by using the comparison signal Scs, it is possible to generate the digital input Din for determining bit0 without waiting for the processing of the logic circuit 240b and the D flip-flop circuit 242b.

The successive approximation register 26 uses the data signal Dca output from the D flip-flop circuit 242a corresponding to a higher-order bit than the (n−1)-th bit from the most significant bit in addition to the comparison signal Scs in order to generate the digital input Din for determining the n-th (herein, n is an integer of 3 or larger) bit from the most significant bit of the output signal Dout.

Herein also, an example of n=3 will be described. In this case, the successive approximation register 26 generates the digital input Din for determining bit0. At that time, the successive approximation register 26 uses the data signal Dca output from the D flip-flop circuit 242a corresponding to bit2 (most significant bit). When generating the digital input Din for determining bit0, since the data signal Dca is already stored in the D flip-flop circuit 242a, the data signal Dca can be used without delay. Note that, the successive approximation register 26 may use the comparison signal Scs obtained by the D flip-flop circuit 220 capturing the comparison result Scom for determining bit1 in order to generate the digital input Din for determining bit0.

As described above, by selecting the signal to be used from the signals output from the D flip-flop circuits 220 and 242a to 242c according to the generated digital signal Din, it is possible to accurately generate the digital signal Din corresponding to the comparison result Scom of the comparator 12 at high speed.

The successive approximation register 26 includes a plurality of selectors 260a to 260c. Each of the plurality of selectors 260a to 260c acquires the corresponding signal among the data signals Dca to Dcc output from the corresponding one of the plurality of D flip-flop circuits 242a to 242c and the comparison signal Scom. Each of the plurality of selectors 260a to 260c selects one of the acquired comparison signal Scom and data signals Dca to Dcc. The digital input Din is generated on the basis of the signal selected by the selectors 260a to 260c.

The selector 260a selects one of the comparison signal Scs and the data signal Dca, and outputs a selected signal Dina. The signal Dina corresponds to bit2 (most significant bit) of the digital input Din. A selector 260b selects one of the comparison signal Scs and the data signal Dcb, and outputs a selected signal Dinb. The signal Dinb corresponds to bit1 of the digital input Din. The selector 260c selects one of the comparison signal Scs and the data signal Dcc, and outputs a selected signal Dinc. The signal Dinc corresponds to bit0 (least significant bit) of the digital input Din. By integrating these signals Dina to Dinc, the digital input Din to be input to the capacitive DAC 10 is generated.

When n is set to an integer of 3 or larger, the selector corresponding to the (n−1)-th bit from the most significant bit of the output signal Dout selects the comparison signal Scs obtained by the D flip-flop circuit 220 capturing the comparison result Scom for determining the (n−1)-th bit from the most significant bit in order to generate the digital input Din for determining the n-th bit from the most significant bit. Furthermore, the selector corresponding to a higher-order bit than the (n−1)-th bit from the most significant bit selects the data signal output from the corresponding D flip-flop circuit in order to generate the digital input Din for determining the n-th bit from the most significant bit.

Herein, an example of n=3 will be described. That is, operations of the selectors 260a to 260c for generating the digital signal Din for determining bit0 will be described. In this case, the selector 260b corresponding to bit1 selects the comparison signal Scs obtained by the D flip-flop circuit 220 capturing the comparison result Scom for determining bit1. Furthermore, the selector 260a corresponding to bit2 selects the data signal Dca output from the corresponding D flip-flop circuit 242a. At that time, the D flip-flop circuit 242c corresponding to bit0 may select the data signal Dcc (signal stored in advance) output from the corresponding D flip-flop circuit 242c. As a result, the digital signal Din corresponding to the comparison result Scom of the comparator 12 can be generated at high speed.

Note that, when generating the digital signal Din for determining bit1, the selector 260a selects the comparison signal Scs obtained by the D flip-flop circuit 220 capturing the comparison result Scom for determining bit2. At that time, the selectors 260b and 260c may select the data signals Dcb and Dcc stored in advance in the D flip-flop circuits 242b and 242c, respectively.

The data signal latch 28 includes D flip-flop circuits 280a to 280c. Each of the D flip-flop circuits 280a to 280c operates in synchronization with the D flip-flop circuits 220 and 242a to 242c. Specifically, the D flip-flop circuits 280a to 280c hold the data signals Dca to Dcc and output the data Da to Dc, respectively, in synchronization with the clock signal CLK. By integrating data the Da to Dc, a 3-bit output signal Dout is generated.

According to the successive approximation ADC 1 according to the present embodiment, in the control circuit 20, the comparator signal Scom from the comparator 12 is captured in the D flip-flop circuit 220 (reference register). The comparator signal Scom captured by the D flip-flop circuit 220 is captured by the D flip-flop circuits 242a to 242c (comparison registers). As a result, even when a delay corresponding to the successive approximation occurs in the comparator signal Scom, the D flip-flop circuit 220 can reset the delay by capturing the comparator signal Scom. As a result, a variation in delay of the comparison signals Sia to Sic captured by the D flip-flop circuits 242a to 242c, respectively, is suppressed. As a result, as for bit2 to bit0, an offset of the reference of low and high is suppressed, and DNL can be improved.

### Second Embodiment

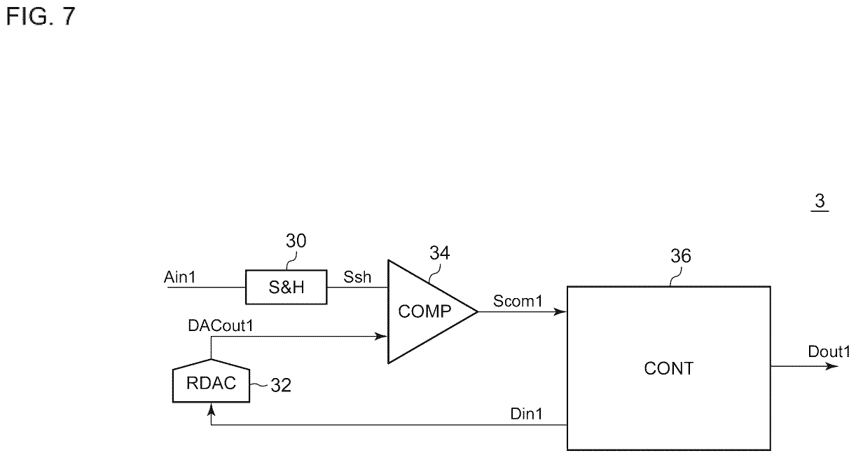

FIG. 7 is a schematic block diagram of a successive approximation ADC 3 according to a second embodiment. The successive approximation ADC 3 according to the second embodiment is different from the successive approximation ADC 1 according to the first embodiment mainly in that a resistive DAC 32 (resistive D/A converter) is provided instead of the capacitive DAC 10. Note that each configuration of the successive approximation ADC 1 according to the first embodiment and each configuration of the successive approximation ADC 3 according to the second embodiment can be optionally combined.

The successive approximation ADC 3 according to the second embodiment generates a digital output signal Dout1 corresponding to an analog input signal Ain1. The output signal Dout1 may be formed of digital data of any number of bits, but in the present embodiment, the output signal Dout1 is assumed to be 3-bit digital data as in the first embodiment. The successive approximation ADC 3 according to the second embodiment includes a sample-hold circuit 30, a resistive DAC 32, a comparator 34, and a control circuit 36.

The sample-hold circuit 30 samples the analog input signal Ain1 and holds a sampled signal. The sample-hold circuit 30 inputs a held signal Ssh to the comparator 34. The capacitive DAC 32 includes a plurality of resistive elements and inputs an analog output signal DACout1 corresponding to a digital input Din1 to the comparator 34.

The comparator 34 compares the signal Ssh from the sample-hold circuit 30 with the output signal DACout1 from the resistive DAC 32 and inputs a comparator signal Scom1 indicating a comparison result to the control circuit 36. The comparator 34 successively compares the signal Ssh from the sample-hold circuit 30 and the output signal DACout1 from the resistive DAC 32 for each of bit2 to bit0 of the output signal Dout1 and inputs the comparator signal Scom1 to the control circuit 36 for each comparison.

The control circuit 36 generates the digital input Din1 on the basis of the comparator signal Scom1. The digital output signal Dout1 is generated on the basis of the comparator signal Scom1 of bit2 to bit0 of the output signal Dout1. The control circuit 36 according to the second embodiment may have substantially the same configuration as the control circuit 20 according to the first embodiment.

Even in a case where the successive approximation ADC 3 is configured to include the resistive DAC 32 in this manner, DNL can be improved similarly to the successive approximation ADC 1 according to the first embodiment.

### Supplement

Although the embodiment according to the present disclosure has been described using specific terms, this description is merely an example for assisting understanding, and does not limit the present disclosure or claims, and the scope of the present disclosure is defined by claims. Furthermore, not only the embodiments but also embodiments, examples, and variations not herein described are included in the scope of the present disclosure.

### Additional Note

The technology disclosed in the present specification can be understood as follows in one aspect.

### Item 1

A successive approximation A/D converter that generates a digital output signal corresponding to an analog input signal, the successive approximation A/D converter including:

a D/A converter that generates an analog output signal including an analog signal corresponding to a digital input;

a comparator that outputs a comparison result between the analog signal and the analog input signal; and

a control circuit that generates the digital input on the basis of the comparison result, in which

the comparator successively outputs the comparison result in order to determine each bit from a most significant bit to a least significant bit of the digital output signal,

the control circuit includes a reference register and a plurality of comparison registers synchronized with the reference register,

the reference register outputs a comparison signal obtained by capturing the comparison result, and

each of the plurality of comparison registers captures the comparison signal for determining a corresponding bit from the most significant bit to the least significant bit, and outputs a data signal indicating each bit from the most significant bit to the least significant bit.

### Item 2

The successive approximation A/D converter according to the item 1, in which

the control circuit further includes a successive approximation register that generates the digital input on the basis of the comparison result, and

the successive approximation register uses the comparison signal obtained by the reference register capturing the comparison result for determining an (n−1)-th bit from the most significant bit in order to generate the digital input for determining an n-th (n is an integer of 2 or larger) bit from the most significant bit.

### Item 3

The successive approximation A/D converter according to the item 2, in which

the successive approximation register uses the comparison signal obtained by the reference register capturing the comparison result for determining an (n−1)-th bit from the most significant bit, and the data signal output from the comparison register corresponding to a higher-order bit than the (n−1)-th bit from the most significant bit in order to generate the digital input for determining the n-th (n is an integer of 3 or larger) bit from the most significant bit.

### Item 4

The successive approximation A/D converter according to the item 3, in which

the successive approximation register includes a plurality of selectors that respectively acquires a data signal output from a corresponding comparison register among the plurality of comparison registers and the comparison signal and selects one of the acquired signals,

the selector corresponding to the (n−1)-th bit from the most significant bit selects the comparison signal obtained by the reference register capturing the comparison result for determining the (n−1)-th bit from the most significant bit in order to generate the digital input for determining the n-th bit from the most significant bit, and

the selector corresponding to a higher-order bit than the (n−1)-th bit from the most significant bit selects the data signal output by the corresponding comparison register in order to generate the digital input for determining the n-th bit from the most significant bit.

### Item 5

The successive approximation A/D converter according to any one of the items 1 to 4, in which

the reference register includes a D flip-flop circuit.

### Item 6

The successive approximation A/D converter according to the item 5, in which

each of the reference register and the plurality of comparison registers includes the D flip-flop circuit and is configured to operate in response to an identical clock signal.

What is claimed is:

1. A successive approximation A/D converter structured to generate a digital output signal corresponding to an analog input signal, the successive approximation A/D converter comprising:
a D/A converter structured to generate an analog output signal including an analog signal corresponding to a digital input;
a comparator structured to output a comparison result between the analog signal and the analog input signal; and
a control circuit structured to generate the digital input on the basis of the comparison result, wherein
the comparator successively outputs the comparison result in order to determine each bit from a most significant bit to a least significant bit of the digital output signal,
the control circuit includes a reference register and a plurality of comparison registers synchronized with the reference register,
the reference register outputs a comparison signal obtained by capturing the comparison result, and
each of the plurality of comparison registers captures the comparison signal for determining a corresponding bit from the most significant bit to the least significant bit, and outputs a data signal indicating each bit from the most significant bit to the least significant bit.

2. The successive approximation A/D converter according to claim 1, wherein
the control circuit further includes a successive approximation register that generates the digital input on the basis of the comparison result, and
the successive approximation register uses the comparison signal obtained by the reference register capturing the comparison result for determining an (n−1)-th bit from the most significant bit in order to generate the digital input for determining an n-th (n is an integer of 2 or larger) bit from the most significant bit.

3. The successive approximation A/D converter according to claim 2, wherein
the successive approximation register uses the comparison signal obtained by the reference register capturing the comparison result for determining the (n−1)-th bit from the most significant bit, and the data signal output from the comparison register corresponding to a higher-order bit than the (n−1)-th bit from the most significant bit in order to generate the digital input for determining the n-th (n is an integer of 3 or larger) bit from the most significant bit.

4. The successive approximation A/D converter according to claim 3, wherein
the successive approximation register includes a plurality of selectors that respectively acquires a data signal output from a corresponding comparison register among the plurality of comparison registers and the comparison signal and selects one of the acquired signals,
the selector corresponding to the (n−1)-th bit from the most significant bit selects the comparison signal obtained by the reference register capturing the comparison result for determining the (n−1)-th bit from the most significant bit in order to generate the digital input for determining the n-th bit from the most significant bit, and
the selector corresponding to a higher-order bit than the (n−1)-th bit from the most significant bit selects the data signal output by the corresponding comparison register in order to generate the digital input for determining the n-th bit from the most significant bit.

5. The successive approximation A/D converter according to claim 1, wherein
the reference register includes a D flip-flop circuit.

6. The successive approximation A/D converter according to claim 5, wherein
each of the reference register and the plurality of comparison registers includes the D flip-flop circuit, and is configured to operate in response to an identical clock signal.
